(19) United States
(12) Patent Application Publication
(10) Pub. No.: US 2013/0301753 A1
(43) Pub. Date: Nov. 14, 2013

(54) CIRCUIT DEVICE AND ELECTRONIC APPARATUS

(71) Applicant: SEIKO EPSON CORPORATION, Tokyo (JP)

(72) Inventor: Toshiyuki MISAWA, Matsumoto-shi (JP)

(73) Assignee: Seiko Epson Corporation, Tokyo (JP)

(21) Appl. No.: 13/889,233

(22) Filed: May 7, 2013

(30) Foreign Application Priority Data
May 8, 2012 (JP) 2012-106544

(51) Int. Cl. H04L 1/00; H03H 11/04

(52) U.S. Cl. CPC H04L 1/0041; H03H 11/0427
USPC 375/297

(57) ABSTRACT

A circuit device includes a communication circuit that includes at least one of a reception circuit and a transmission circuit, and an adjustment signal generating circuit that outputs an adjustment signal which adjusts a transconductance of an adjustment target circuit included in the communication circuit. The adjustment signal generating circuit performs a generation process of the adjustment signal, accumulates charge corresponding to the generated adjustment signal in a capacitor, and outputs the adjustment signal based on the charge accumulated in the capacitor to the adjustment target circuit.

This application claims priority to Japanese Patent Application No. 2012-106544, filed May 8, 2012, the entirety of which is hereby incorporated by reference.

### BACKGROUND

1. Technical Field

The present invention relates to a circuit device and an electronic apparatus.

2. Related Art

With the recent widespread use of portable wireless apparatuses, a wireless circuit device which has a smaller size and lower power consumption is required. For example, as a filter circuit, a complex band-pass filter (complex BPF) circuit formed by an Operational Transconductance Amplifier (OTA) and a capacitor is used, thereby realizing one chip of the wireless circuit device.

However, since, in a practical circuit device, a fluctuation in characteristics of transconductance and passive elements due to a manufacturing disparity, a fluctuation in a power supply voltage or temperature, or the like cannot be avoided, filter characteristics fluctuate, and, as a result, there is a problem in that an operation of a wireless apparatus becomes unstable, and the like.

In order to solve this problem, for example, JP-A-2008-167000 discloses a method in which transconductance of an OTA is adjusted so as to correct the fluctuation in filter characteristics. However, in this method, a circuit for generating an adjustment signal used to adjust the transconductance is required to be provided, and thus there is a problem in that power consumption increases.

### SUMMARY

An advantage of some aspects of the invention is to provide a circuit device and an electronic apparatus capable of correcting a transconductance due to a manufacturing disparity, a fluctuation in a power supply voltage or temperature, or the like, with high efficiency.

An aspect of the invention is directed to a circuit device including a communication circuit that includes at least an adjustment target circuit; and an adjustment signal generating circuit that outputs an adjustment signal which adjusts a transconductance of the adjustment target circuit, wherein the adjustment signal generating circuit performs a generation process of the adjustment signal, accumulates charge corresponding to the generated adjustment signal in a capacitor, and outputs the adjustment signal based on the charge accumulated in the capacitor to the adjustment target circuit.

With this configuration, the adjustment signal generating circuit can generate the adjustment signal, accumulate charge in the capacitor, and adjust a transconductance of the adjustment target circuit by using the adjustment signal based on the charge accumulated in the capacitor, and thereby it is possible to correct deviation of the transconductance due to a manufacturing disparity, a fluctuation in a power supply voltage or temperature, or the like with high efficiency. As a result, it is possible to realize more stable and reliable wireless communication.

In the aspect of the invention, the adjustment signal generating circuit may perform the generation process of the adjustment signal, accumulate charge corresponding to the generated adjustment signal in the capacitor, and output the adjustment signal based on the charge accumulated in the capacitor to the adjustment target circuit, during a signal non-communication period which is a period when the communication circuit does not perform transmission or reception of a communication signal.

With this configuration, the adjustment signal generating circuit does not perform the generation process of the adjustment signal and can adjust a transconductance of the adjustment target circuit by using the adjustment signal based on charge accumulated in the capacitor during a signal communication period.

In the aspect of the invention, the circuit device may further include a control unit that controls the adjustment signal generating circuit, and, the control unit may set at least a part of the adjustment signal generating circuit in a disenable state or a low power consumption mode after the adjustment signal is generated.

With this configuration, since power consumption of the adjustment signal generating circuit can be reduced after the adjustment signal is generated, it is possible to output the adjustment signal without increasing power consumption during communication.

In the aspect of the invention, the adjustment signal generating circuit may include a replica circuit of the adjustment target circuit, the adjustment signal generating circuit may perform a feedback process by using a negative feedback loop including the replica circuit when the adjustment signal is generated, and the control unit may switch the negative feedback loop to an open loop after the adjustment signal is generated.

With this configuration, the negative feedback loop is switched to the open loop after the adjustment signal is generated, and thereby it is possible to maintain the adjustment signal to be constant even if the replica circuit or the like is set in a disenable state or a low power consumption mode.

In the aspect of the invention, the replica circuit may be a complex band-pass filter circuit, and the adjustment signal may be a signal which adjusts a central frequency of the complex band-pass filter circuit.

With this configuration, the adjustment signal generating circuit adjusts a central frequency of the complex band-pass filter circuit by using the negative feedback loop including the replica circuit, so as to generate the adjustment signal.

In the aspect of the invention, the replica circuit may include a variable capacitor of which a capacitance value is set to be variable.

With this configuration, it is possible to set a capacitance value of the variable capacitor to a desired value, for example, in a testing process before shipment from the factory is performed.

In the aspect of the invention, the adjustment signal generating circuit may accumulate charge corresponding to an error from a desired value of the transconductance of the adjustment target circuit in the capacitor, and generate the adjustment signal.

With this configuration, the adjustment signal generating circuit can output the adjustment signal based on the charge accumulated in the capacitor and adjust a transconductance of the adjustment target circuit.

In the aspect of the invention, the adjustment signal generating circuit may further include a reference signal generating circuit that outputs a first signal and a second signal of which a phase is different from a phase of the first signal by 90 degrees to the replica circuit; a mixer to which the second signal and a first output signal from the replica circuit, or the first signal and a second output signal from the replica circuit are input; and a smoothing circuit that smooths an output signal from the mixer, the mixer may detect a phase error of two input signals, and the smoothing circuit may output a voltage corresponding to the detected phase error.

With this configuration, the adjustment signal generating circuit can generate the adjustment signal on the basis of a voltage corresponding to the detected phase error.

In the aspect of the invention, the adjustment signal generating circuit may further include an integration circuit that accumulates charge corresponding to the detected phase error in the capacitor, and the adjustment signal generating circuit may generate and output the adjustment signal on the basis of the charge accumulated in the capacitor.

With this configuration, the adjustment signal generating circuit can accumulate charge corresponding to the detected phase error in the capacitor, output the adjustment signal based on the charge accumulated in the capacitor, and adjust a transconductance of the adjustment target circuit.

In the aspect of the invention, the adjustment signal generating circuit may further include a switch circuit, and the control unit may control the switch circuit so as to perform control of a feedback process by using the negative feedback loop when the adjustment signal is generated, and so as to switch the negative feedback loop to an open loop after the adjustment signal is generated.

With this configuration, it is possible to generate the adjustment signal through the feedback process, and to switch the negative feedback loop to the open loop after the adjustment signal is generated.

In the aspect of the invention, the adjustment signal generating circuit may function as a first adjustment signal generating circuit, and the first adjustment signal generating circuit may output a first adjustment signal to a complex band-pass filter circuit that is one of components of the communication circuit as the adjustment signal.

With this configuration, it is possible to correct deviation from a desired value of a central frequency or the like of the complex band-pass filter circuit due to a manufacturing disparity, a fluctuation in a power supply voltage or temperature, or the like. As a result, it is possible to realize more stable and reliable wireless communication.

In the aspect of the invention, the complex band-pass filter circuit included in the communication circuit may include a variable capacitor of which a capacitance value is set to be variable, and the first adjustment signal generating circuit may adjust a central frequency of the complex band-pass filter circuit by using the first adjustment signal after a capacitance value of the variable capacitor is adjusted.

With this configuration, since a disparity range of a capacitance value can be reduced by adjusting the capacitance value of the variable capacitor, for example, in a testing process when shipment from the factory is performed, it is possible to adjust a central frequency in a narrow adjustment range with the first adjustment signal generating circuit when used for practical communication.

In the aspect of the invention, the adjustment signal generating circuit may function as a second adjustment signal generating circuit, and the second adjustment signal generating circuit may output a second adjustment signal to at least one of a low-noise amplifier, a mixer, a PLL circuit, and a power amplifier included in the communication circuit, as the adjustment signal.

With this configuration, it is possible to correct deviation of circuit characteristics of the low-noise amplifier, the mixer, the PLL circuit, or the power amplifier due to a manufacturing disparity, a fluctuation in a power supply voltage or temperature, or the like. As a result, it is possible to realize more stable and reliable wireless communication.

Another aspect of the invention is directed to an electronic apparatus including any one of the circuit devices described above.

### BRIEF DESCRIPTION OF THE DRAWINGS

The invention will be described with reference to the accompanying drawings, wherein like numbers reference like elements.

FIG. 1 is a basic configuration example of a circuit device.

FIG. 2 is a diagram illustrating a packet communication period and a packet non-communication period.

FIG. 3 is a diagram illustrating a basic configuration example of an adjustment signal generating circuit.

FIG. 4 is a diagram illustrating a specific configuration example of a smoothing circuit, a switch circuit, an integration circuit, a correction current generating circuit, and a current adding circuit.

FIGS. 5A and 5B are diagrams respectively illustrating second and third configuration examples of the switch circuit.

FIG. 6 is a diagram illustrating a configuration example of a complex BPF circuit.

FIGS. 7A and 7B are diagrams illustrating detection of deviation of a central frequency by the adjustment signal generating circuit.

FIG. 8 is a diagram illustrating a first configuration example of an operational transconductance amplifier.

FIG. 9 is a diagram illustrating a second configuration example of the operational transconductance amplifier.

FIG. 10 is a diagram illustrating a configuration example of a variable capacitor.

FIG. 11 is a diagram illustrating a relationship between a tail current and transconductance of the OTA.

FIG. 12 is a diagram illustrating adjustment of a capacitance value using a variable capacitor.

FIG. 13 is a diagram illustrating a configuration example of a mixer.

FIG. 14 is a diagram illustrating a configuration example of a PLL circuit.

FIG. 15 is a diagram illustrating a configuration example of a voltage controlled oscillation circuit.

FIG. 16 is a diagram illustrating a configuration example of a low-noise amplifier.

FIG. 17 is a diagram illustrating a configuration example of an electronic apparatus.

### DESCRIPTION OF EXEMPLARY EMBODIMENTS

Hereinafter, embodiments of the invention will be described in detail. In addition, the embodiment described below does not improperly restrict content of the invention disclosed in the appended claims, and all the configurations described in the embodiment are not essential as solving means of the invention.

### 1. Circuit Device

### 1-1. Circuit Device and Adjustment Signal Generating Circuit

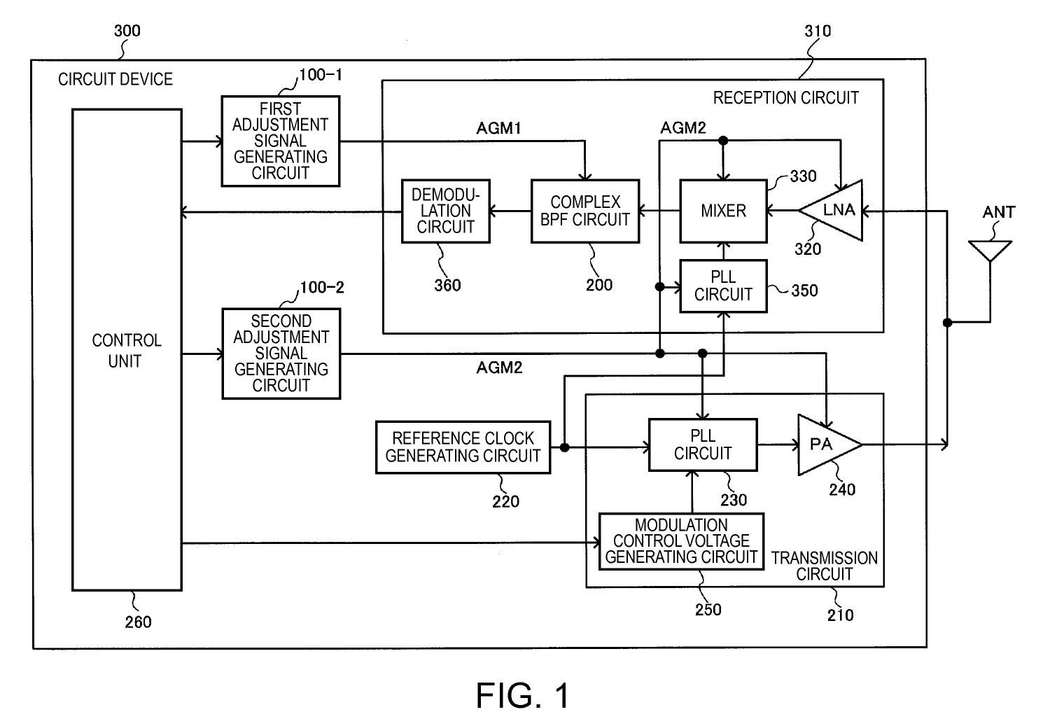

FIG. 1 shows a basic configuration example of a circuit device 300 of the embodiment. The circuit device 300 of the embodiment includes a transmission circuit (a communication circuit in a broad sense) 210, a reception circuit (a communication circuit in a broad sense) 310, a first adjustment signal generating circuit 100-1, a second adjustment signal generating circuit 100-2, a reference clock generating circuit 220, and a control unit 260. In addition, the circuit device 300 of the embodiment is not limited to the configuration of FIG. 1, and may have various modifications in which some of the constituent elements thereof are omitted or replaced with other constituent elements, other constituent elements are added thereto, and the like. For example, the communication circuit may be either a transmission circuit or a reception circuit. In addition, either one of the first and second adjustment signal generating circuits 100-1 and 100-2 may be omitted.

The transmission circuit 210 includes a transmission Phase Locked Loop (PLL) circuit 230, a modulation control voltage generating circuit 250, and a power amplifier (PA) 240. The reception circuit 310 includes a low-noise amplifier (LNA) 320, a mixer 330, a reception PLL circuit 350, a complex BPF circuit 200, and a demodulation circuit 360.

The transmission PLL circuit 230 generates a signal with a frequency of a carrier wave on the basis of a reference clock from the reference clock generating circuit 220. The modulation control voltage generating circuit 250 generates a modulation control voltage signal on the basis of data transmitted from the control unit 260 so as to be output to the transmission PLL circuit 230. The power amplifier (PA) 240 amplifies an output signal of the transmission PLL circuit 230 so as to be supplied to an antenna ANT.

The reference clock generating circuit 220 generates a reference clock which is output to the transmission PLL circuit 230 and the reception PLL circuit 350.

The low-noise amplifier (LNA) 320 amplifies a received signal which is input from the antenna ANT. The mixer 330 performs frequency conversion from a reception frequency to an intermediate frequency. The complex BPF circuit 200 removes an unnecessary frequency component from the signal having undergone the frequency conversion so as to output a desired signal. The reception PLL circuit 350 generates a signal with a local reference frequency on the basis of the reference clock from the reference clock generating circuit 220, so as to be output to the mixer 330. The demodulation circuit 360 demodulates of a signal of a desired wave so as to extract necessary data.

The first and second adjustment signal generating circuits 100-1 and 100-2 respectively first and second adjustment signals AGM1 and AGM2 for adjusting a transconductance of an adjustment target circuit included in the communication circuit. Specifically, as shown in FIG. 1, the first adjustment signal generating circuit 100-1 outputs the first adjustment signal AGM1 to the complex band-pass filter (BPF) circuit 200 included in the reception circuit 310. In addition, the second adjustment signal generating circuit 100-2 outputs second adjustment signal AGM2 to at least one of the low-noise amplifier (LNA) 320, the mixer 330, and the reception PLL circuit 350 included in the reception circuit 310, and the transmission PLL circuit 230 and the power amplifier (PA) 240 included in the transmission circuit 210.

According to the circuit device 300 of the embodiment, the transconductance gm of an adjustment target circuit is adjusted using the adjustment signals AGM1 and AGM2, and thereby it is possible to compensate a fluctuation (deviation) in gm from a desired value (design value) due to a manufacturing disparity, a fluctuation in a power supply voltage or temperature, or the like. As a result, it is possible to realize more stable and reliable wireless communication.

The first and second adjustment signal generating circuits 100-1 and 100-2 generate the adjustment signals AGM1 and AGM2, and accumulate charge corresponding to the generated adjustment signals AGM1 and AGM2 in a capacitor. In addition, the adjustment signals AGM1 and AGM2 based on the charge accumulated in the capacitor are output to an adjustment target circuit. The capacitor may be provided in the adjustment signal generating circuits 100-1 and 100-2.

In addition, the first and second adjustment signal generating circuits 100-1 and 100-2 may generate the adjustment signals AGM1 and AGM2 during a packet non-communication period when the communication circuit does not perform transmission or reception, accumulate charge corresponding to the generated adjustment signals AGM1 and AGM2 in the capacitor, and output the adjustment signals AGM1 and AGM2 based on the charge accumulated in the capacitor to an adjustment target circuit. In this way, since the adjustment signals AGM1 and AGM2 are generated during the packet non-communication period when packet communication is not performed, and the adjustment signals AGM1 and AGM2 are not generated and the adjustment signals AGM1 and AGM2 can be output based on the charge accumulated in the capacitor during a packet communication period, it is possible to reduce power consumption during communication.

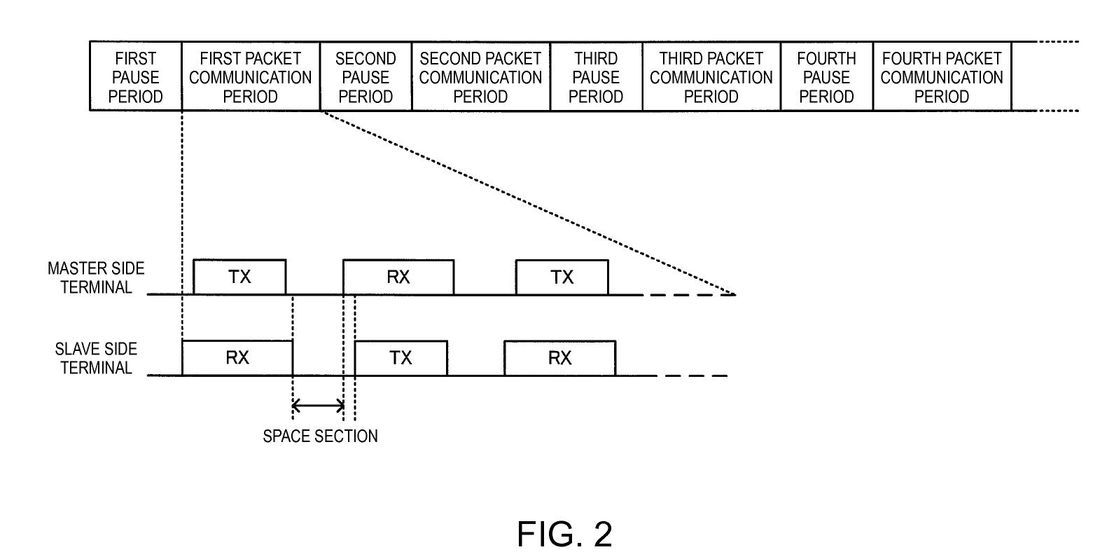

FIG. 2 is a diagram illustrating the packet communication period and the packet non-communication period. The packet non-communication period is a period when a communication packet is not transmitted or received, and includes, for example, a pause period shown in FIG. 2. The pause period is a period preceding the packet communication period or a period interposed between two packet communication periods, and is, for example, a sleep mode period, or the like. A first pause period is initially provided. Then, a first packet communication period is provided, and, next, a second pause period is provided. In addition, a second packet communication period, a third pause period, and a third packet communication period are continued.

In each packet communication period, a transmission section TX, a reception section RX, and a space section are provided. Specifically, for example, as shown in FIG. 2, in a case of a master side terminal, the transmission section TX, the space section, the reception section RX, the space section, the transmission section TX, . . . are provided in this order. In addition, in a case of a slave side terminal, the reception section RX, the space section, the transmission section TX, the space section, the reception section RX, . . . are provided in this order.

The packet non-communication period may be the space section, or may be both of the pause period or the space section. Here, the space section is a section when a transmission process or a reception process is not performed in each packet communication period. Alternatively, the space section is a section when neither of the master side terminal and the slave side terminal performs a transmission process or a reception process. Specifically, the space section is, for example, a section for changing between transmission and reception modes or synchronization between transmission and reception. In addition, the circuit device 300 of the embodiment is applicable to both the master side terminal and the slave side terminal.

The adjustment signal generating circuits 100-1 and 100-2 performs a generation process of the adjustment signals AGM1 and AGM2, accumulate charge corresponding to the generated adjustment signals AGM1 and AGM2 in the capacitor, and output the adjustment signals AGM1 and AGM2 based on the charge accumulated in the capacitor to an adjustment target circuit, during the first pause period. In addition, for example, during the first packet communication period, a generation process of the adjustment signals AGM1 and AGM2 may not be performed, and the adjustment signals AGM1 and AGM2 may be output based on the charge accumulated in the capacitor. Further, the adjustment signal generating circuits 100-1 and 100-2 may perform a generation process of the adjustment signals AGM1 and AGM2 during the second pause period, and may perform a generation process of the adjustment signals AGM1 and AGM2 during the third pause period or the fourth pause period, or the pause periods thereafter.

In addition, the adjustment signal generating circuits 100-1 and 100-2 may perform a generation process of the adjustment signals AGM1 and AGM2, accumulate charge corresponding to the generated adjustment signals AGM1 and AGM2 in the capacitor, and output the adjustment signals AGM1 and AGM2 based on the charge accumulated in the capacitor to an adjustment target circuit, during the space section of the packet communication period. In addition, for example, during the transmission section TX or the reception section RX which is subsequent to the space section, a generation process of the adjustment signals AGM1 and AGM2 may not be performed, and the adjustment signals AGM1 and AGM2 may be output based on the charge accumulated in the capacitor.

In addition, the adjustment signal generating circuits 100-1 and 100-2 are not necessarily required to generate the adjustment signals at every space section and may generate the adjustment signals in at least one space section.

The first and second adjustment signal generating circuits 100-1 and 100-2 accumulate charge corresponding to an error (deviation) from a desired value of a transconductance of an adjustment target circuit in the capacitor, and generate the adjustment signals AGM1 and AGM2 on the basis of the charge accumulated in the capacitor. In this way, the transconductance gm of an adjustment target circuit is adjusted using the adjustment signals AGM1 and AGM2, and thereby it is possible to compensate a fluctuation (deviation) in gm from a desired value (design value) due to a manufacturing disparity, a fluctuation in a power supply voltage or temperature, or the like.

The first adjustment signal generating circuit 100-1 includes a replica circuit of the complex BPF circuit 200 which is an adjustment target circuit, and performs a feedback process using a negative feedback loop including the replica circuit when the adjustment signal is generated. The replica circuit is a complex band-pass filter circuit, specifically, a first-order complex BPF circuit as described later, and has the same central frequency as the complex BPF circuit 200 included in the reception circuit 310. The first adjustment signal AGM1 adjusts the central frequency of the complex BPF circuit 200. The complex BPF circuit and the adjustment of the central frequency will be described in detail later.

In addition, the second adjustment signal generating circuit 100-2 has the same configuration as the first adjustment signal generating circuit 100-1, and performs a feedback process using a negative feedback loop including the replica circuit when the adjustment signal is generated.

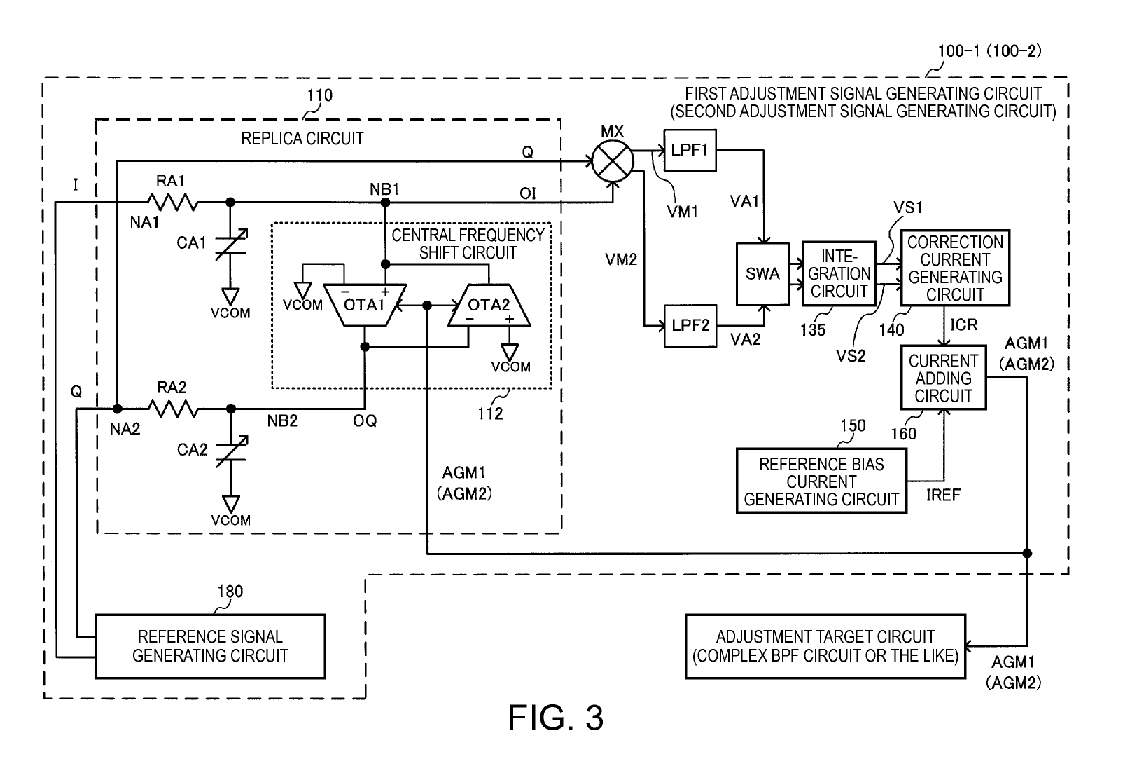

The negative feedback loop is a negative feedback loop used for the first and second adjustment signal generating circuits 100-1 and 100-2 to generate the adjustment signals AGM1 and AGM2, and includes, specifically, a replica circuit 110, a mixer MX, smoothing circuits LPF1 and LPF2, a switch circuit SWA, an integration circuit 135, a correction current generating circuit 140, and a current adding circuit 160, shown in FIG. 3.

The control unit 260 performs a control process of transmission and reception, or control of data communication with an external circuit (a host device or the like) of the circuit device 300. Specifically, for example, the control unit 260 performs control of a setting process of a carrier frequency, a modulation process, a demodulation process, and the like.

Further, the control unit 260 controls the first and second adjustment signal generating circuits 100-1 and 100-2. Specifically, the control unit 260 sets at least some circuits of the adjustment signal generating circuits 100-1 and 100-2 in a disenable state or a low power consumption mode after the adjustment signals AGM1 and AGM2 are generated. In addition, the control unit 260 switches the negative feedback loop to an open loop after the adjustment signals AGM1 and AGM2 are generated. In other words, the adjustment signals AGM1 and AGM2 are generated by performing a feedback process using the negative feedback loop, and the negative feedback loop is switched to the open loop after the adjustment signals AGM1 and AGM2 are generated. In addition, at least some circuits of the adjustment signal generating circuits 100-1 and 100-2 are set in a disenable state or a low power consumption mode. In this way, power consumption of the adjustment signal generating circuits 100-1 and 100-2 is reduced, or can be suppressed to the minimum, and thus it is possible to reduce power consumption during communication.

In addition, in the following description, in a case where the first and second adjustment signal generating circuits 100-1 and 100-2 are not required to be differentiated from each other, they are simply referred to as an adjustment signal generating circuit 100 or adjustment signal generating circuits 100. Similarly, in a case where the first and second adjustment signals AGM1 and AGM2 are not required to be differentiated from each other, they are simply referred to as an adjustment signal AGM or adjustment signals AGM.

FIG. 3 shows a basic configuration example of the first and second adjustment signal generating circuits 100-1 and 100-2 of the embodiment. The first and second adjustment signal generating circuits 100-1 and 100-2 may have the same circuit configuration. The adjustment signal generating circuit 100 includes the replica circuit 110, the mixer MX, the smoothing circuits LPF1 and LPF2, the switch circuit SWA, the integration circuit 135, the correction current generating circuit 140, a reference bias current generating circuit 150, the current adding circuit 160, and a reference signal generating circuit 180. In addition, the adjustment signal generating circuit 100 of the embodiment is not limited to the configuration of FIG. 3, and may have various modifications in which some of the constituent elements thereof are omitted or replaced with other constituent elements, other constituent elements are added thereto, and the like. For example, any one reference signal generating circuit 180 of the first and second adjustment signal generating circuits 100-1 and 100-2 may be omitted, and a signal from the other reference signal generating circuit 180 may be supplied.

The adjustment signal generating circuit 100 outputs the adjustment signal AGM to an adjustment target circuit (for example, the complex BPF circuit 200 or the like) which is an adjustment target of a transconductance. The adjustment signal AGM is a signal which adjusts gm of an OTA, an operational amplifier, or the like included in the adjustment target circuit (the complex BPF circuit 200 or the like).

The reference signal generating circuit 180 outputs a first signal I, and a second signal Q of which a phase is different from that of the first signal I by 90 degrees. Specifically, the reference signal generating circuit 180 generates the first signal I and the second signal Q of which voltages vary between a first voltage level VH and a second voltage level VL, so as to be output to the replica circuit 110.

The replica circuit 110 is a complex BPF circuit, is a replica circuit of the adjustment target circuit (complex BPF circuit) 200, and receives the first signal I and the second signal Q of which a phase is different from that of the first signal I by 90 degrees, so as to generate a first output signal OI and a second output signal OQ. Specifically, the replica circuit 110 of FIG. 3 is a first-order complex BPF circuit, and includes a first resistive element RA1, a second resistive element RA2, a first variable capacitor CA1, a second variable capacitor CA2, and a central frequency shift circuit 112.

The first signal I is input to a first input node NA1, and the second signal Q of which a phase is different from that of the first signal I by 90 degrees is input to a second input node NA2. Specifically, for example, if the first signal I is expressed by cos(ωt) as a function of time t, the second signal Q is expressed by sin(ωt). Here, ω is an angular frequency of the first and second signals I and Q.

The first output signal OI is output from a first output node NB1, and the second output signal OQ is output from a second output node NB2.

The first resistive element RA1 is provided between the first input node NA1 and the first output node NB1. In addition, the second resistive element RA2 is provided between the second input node NA2 and the second output node NB2. The first and second resistive elements RA1 and RA2 may be formed, for example, by passive resistive elements using a poly-silicon thin film, or may be formed by an operational transconductance amplifier (OTA). In addition, from the viewpoint of linearity of characteristics of a resistive element, the passive resistive element is preferably used.

The first variable capacitor CA1 has one end connected to the first output node NB1 and the other end connected to, for example, a common potential node VCOM. In addition, the second variable capacitor CA2 has one end connected to the second output node NB2 and the other end connected to, for example, the common potential node VCOM. A configuration example of the first and second variable capacitors CA1 and CA2 will be described later.

The central frequency shift circuit 112 is formed by first and second operational transconductance amplifiers OTA1 and OTA2 provided between the first output node NB1 and the second output node NB2. The first low-pass filter (composed of RA1 and CA1) is connected to the second low-pass filter (RA2 and CA2) via a pair of OTAs (one has a positive polarity and the other has a negative polarity) with different polarities, and thereby a frequency characteristic is shifted by the central frequency ω0 so as to obtain a band-pass filter (first-order complex BPF). The signal I is an input for the first low pass filter and the signal Q is an input for the second low pass filter. The signal OI is an output from the first low pass filter and the signal OQ is an output from the second low pass filter. The whole circuit 110 gives band pass filter characteristics. Here, if a transconductance value of OTA1 and OTA2 is gm, and a capacitance value of the variable capacitors CA1 and CA2 is C, the central frequency ω0 is given by ω0=gm/C.

For example, in FIG. 3, OTA1 has a positive polarity and outputs a first output current on the basis of the first output signal OI which is input to the non-inverting input terminal (+) thereof. The second variable capacitor CA2 is charged by the first output current so as to output the second output signal OQ. In addition, OTA2 has a negative polarity and outputs a second output current on the basis of the second output signal OQ which is input to the inverting input terminal (−) thereof. The first variable capacitor CA1 is charged by the second output current so as to output the first output signal OI.

The non-inverting input terminal (+) of OTA1 is connected to the first output node NB1, the inverting input terminal (−) thereof is connected to the common potential node VCOM, and the output terminal thereof is connected to the second output node NB2. The non-inverting input terminal (+) of OTA2 is connected to the common potential node VCOM, the inverting input terminal (−) thereof is connected to the second output node NB2, and the output terminal thereof is connected to the first output node NB1. The adjustment signals AGM are input to OTA1 and OTA2, and transconductances of OTA1 and OTA2 are adjusted by the adjustment signals AGM.

The common potential node VCOM is a common potential (an analog reference potential, an analog ground) node with respect to an analog signal, and is a node with an intermediate potential, for example, between a first power supply potential (low-potential side power supply potential) VSS and a second power supply potential (high-potential side power supply potential) VDD.

The mixer MX receives the first signal I and the second output signal OQ or the second signal Q and the first output signal OI. The mixer MX detects a phase difference of the first signal I and the second output signal OQ or a phase difference (phase error) of the second signal Q and the first output signal OI, and outputs first and second mixer output signals VM1 and VM2 which are differential signals.

The first smoothing circuit LPF1 smooths the first mixer output signal VM1 from the mixer MX so as to remove an AC component and to output a DC component VA1. The second smoothing circuit LPF2 smooths the second mixer output signal VM2 from the mixer MX so as to remove an AC component and to output a DC component VA2. A voltage difference (VA1−VA2) between the DC components VA1 and VA2 corresponds to a phase difference (phase error) of two signals (for example, Q and OI) input to the mixer MX. In addition, a relationship between a phase difference of two signals (for example, Q and OI) and characteristics of the complex BPF circuit 200 will be described later.

The output signals VM1 and VM2 of the mixer MX are given by the following expressions.

VM1=V0+V(t)/2 (1)

VM2=V0−V(t)/2 (2)

In the expressions, V0 is an offset voltage, and is 0 if the mixer has ideal characteristics, but V0 is not 0 since characteristics of a transistor or the like are deviated from a design value due to a manufacturing disparity in a practical circuit. The offset voltage V0 varies depending on a manufacturing disparity, a fluctuation in a power supply voltage or temperature, or the like. However, the difference VM1−VM2 of the differential signal is taken, thereby removing the offset voltage V0. In this way, since influence such as a manufacturing disparity, a fluctuation in a power supply voltage or temperature, or the like, included in V0 can be canceled out, a phase difference φ of two signals (for example, Q and OI) can be detected with high accuracy. In addition, in the following description, V0 in the expressions will be omitted.

In relation to V(t) of Expressions (1) and (2), for example, if the second signal Q input to MX is set to sin(ωt), and the first output signal OI is set to cos(ωt+φ), the following expression is given.

V(t)=k·(sin(2ωt+φ)−sin φ) (3)

In the expression, k is a constant defined by characteristics of the mixer, and φ is a phase difference of the first output signal OI relative to the first signal I.

The smoothing circuits LPF1 and LPF2 extract DC components of the mixer output signals VM1 and VM2. The output signals VA1 and VA2 of the smoothing circuits LPF1 and LPF2 are given by the following expression from Expressions (1), (2) and (3).

VA1=−k·sin φ/2 (4)

VA2=+k·sin φ/2 (5)

The output signals VA1 and VA2 of the smoothing circuits LPF1 and LPF2 are input to the integration circuit 135 via the switch circuit SWA. The switch circuit SWA performs a switching operation under the control of the control unit 260. The control unit 260 controls the switch circuit SWA so as to switch the negative feedback loop to an open loop. The integration circuit 135 accumulates charge corresponding to the detected phase error in a capacitor CP.

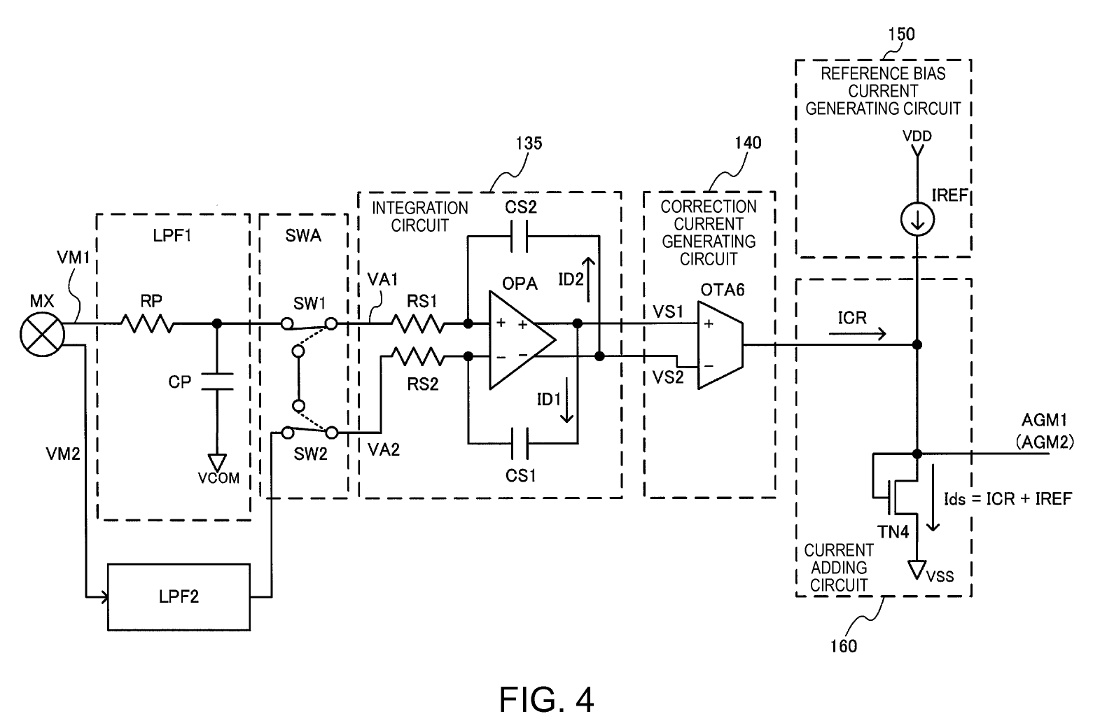

FIG. 4 shows a specific configuration example of the smoothing circuits LPF1 and LPF2, the switch circuit SWA, the integration circuit 135, the correction current generating circuit 140, and the current adding circuit 160. In addition, the smoothing circuits LPF1 and LPF2, the switch circuit SWA, the integration circuit 135, the correction current generating circuit 140, and the current adding circuit 160 of the embodiment are not limited to the configuration of FIG. 4, and may have various modifications in which some of the constituent elements thereof are omitted or replaced with other constituent elements, other constituent elements are added thereto, and the like.

The smoothing circuit LPF1 includes a resistive element RP and the capacitor CP, smooths the mixer output signal VM1, and outputs a DC component as the output signal VA1. In addition, in the same manner as LPF1, the smoothing circuit LPF2 includes a resistive element and a capacitor, smooths the mixer output signal VM2, and outputs a DC component as the output signal VA2.

The switch circuit SWA shown in FIG. 4 corresponds to a first configuration example, and includes switching elements SW1 and SW2. The switching elements SW1 and SW2 perform switching operations under the control of the control unit 260. When SW1 and SW2 are in a state indicated by the solid lines of FIG. 4, a negative feedback loop is formed, and a feedback process is performed. In other words, the output signals VA1 and VA2 of the smoothing circuits LPF1 and LPF2 are input to the integration circuit 135, the adjustment signals AGM are generated based on VA1 and VA2, and the central frequency of the replica circuit 110 which is a first-order complex BPF circuit is shifted by the adjustment signals AGM. In addition, when the central frequency is shifted, a phase difference of the two input signals (for example, Q and OI) of the mixer MX varies, VA1 and VA2 vary so as to correspond to the phase difference which has varied, and, further, the adjustment signals AGM are generated based on VA1 and VA2 which has varied.

On the other hand, when SW1 and SW2 are in a state indicated by the broken lines of FIG. 4, the adjustment signal generating circuit 100 is in an open loop, and a feedback process is not performed. In other words, since a non-inverting input node (+) and an inverting input node (−) of an operational amplifier OPA of the integration circuit 135 are set to the same potential, output currents ID1 and ID2 of the operational amplifier OPA become 0, and thus charge of the capacitors CS1 and CS2 do not vary. Therefore, integration voltages VS1 and VS2 do not also vary, and thus the adjustment signals AGM are maintained in a constant voltage.

During an open loop period, the control unit 260 sets at least some circuits of the adjustment signal generating circuits 100 in a disenable state or a low power consumption mode. Specifically, the reference signal generating circuit 180, OTA1 and OTA2 of the replica circuit 110, and the mixer MX are set in a disenable state or a low power consumption mode. In this way, power consumption of the adjustment signal generating circuits 100 is reduced, or can be suppressed to the minimum, and thus it is possible to reduce power consumption during communication.

The integration circuit 135 includes the operational amplifier OPA, the resistive elements RS1 and RS2, and the capacitors CS1 and CS2, and integrates the output signals VA1 and VA2 of the smoothing circuits LPF1 and LPF2 so as to output the first and second integration voltages VS1 and VS2. If currents which flow from the operational amplifier OPA to the capacitors CS1 and CS2 are respectively indicated by ID1 and ID2, and a capacitance of the capacitors CS1 and CS2 is set to Cs, the integration voltages VS1 and VS2 are given by the following expression.

$$\begin{matrix}VS 1 ( t ) = \frac{1}{Cs} {\int }_{0}^{t} ID 1 ( t ) d t & ( 6 ) \\ VS 2 ( t ) = \frac{1}{Cs} {\int }_{0}^{t} ID 2 ( t ) d t & ( 7 )\end{matrix}$$

In the expressions, if φ<0, VA1>0 and VA2<0 from Expressions (4) and (5), which lead to ID1>0 and ID2<0, and thereby ID1 charges the capacitor CS1, and ID2 discharges the capacitor CS2. On the other hand, if φ>0, VA1<0 and VA2>0, which lead to ID1<0 and ID2>0, and thereby ID1 discharges the capacitor CS1, and ID2 charges the capacitor CS2. In addition, if φ=0, VA1=0 and VA2=0, which lead to ID1=0 and ID2=0, and thereby charge of the capacitors CS1 and CS2 does not vary.

As can be seen from Expressions (6) and (7), VS1 (VS2) increases with the time during the period when ID1 (ID2) is positive, and VS1 (VS2) decreases with the time during the period when ID1 (ID2) is negative. In addition, during the period when ID1 (ID2) is 0, VS1 (VS2) is maintained in a constant value.

The correction current generating circuit 140 includes OTA6 as a voltage controlled current source, and the integration voltage VS1 is input to a non-inverting input terminal (+) thereof and the integration voltage VS2 is input to an inverting input terminal (−) thereof. In addition, a correction current ICR which is proportional to the difference (VS1−VS2) of the integration voltages is generated. The correction current ICR is a current which compensates deviation from a design value of the transconductance (gm) of the OTA included in the complex BPF circuit (an adjustment target circuit in a broad sense) 200. The correction current ICR is given by the following expression when a transconductance value of OTA6 is set to gm6.

ICR=gm6·(VS1−VS2) (8)

The reference bias current generating circuit 150 generates a reference bias current IREF. The reference bias current IREF is a current used as a reference for generating a tail current which gives a design value of the transconductance (gm) of the OTA included in the complex BPF circuit (an adjustment target circuit in a broad sense) 200. In other words, in a case where element characteristics, a power supply voltage, and temperature have values as designed, the reference bias current IREF is a current used as a reference for generating a tail current giving a design value of gm of the OTA. In addition, a relationship between gm of the OTA and the tail current will be described later.

The current adding circuit 160 adds the correction current ICR to the reference bias current IREF. The current obtained by adding the correction current ICR to the reference bias current IREF is a current used as a reference for generating a tail current giving a desired (corrected) gm value of the OTA.

Specifically, the current adding circuit 160 includes an N type transistor TN4, for example, as shown in FIG. 4. A drain current Ids of TN4 is Ids=ICR+IREF, and thus a gate-source voltage of TN4 is output as the adjustment signal AGM. In addition, a configuration example of the OTA and adjustment of gm using the adjustment signal AGM will be described later.

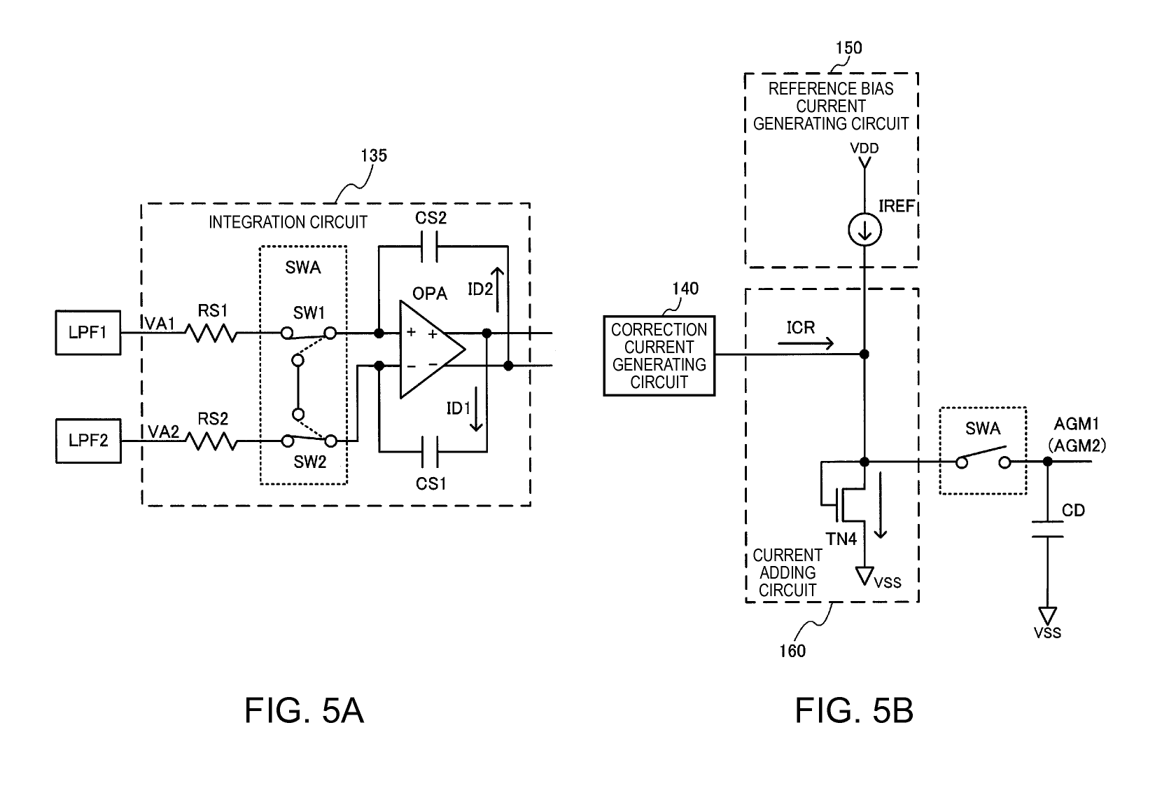

FIG. 5A shows a second configuration example of the switch circuit SWA. The switch circuit SWA of the second configuration example is provided between the resistive elements RS1 and RS2 and the operational amplifier OPA of the integration circuit 135. When SW1 and SW2 are in a state indicated by the solid lines of FIG. 5A, the adjustment signal generating circuit 100 is formed in a closed loop, and the adjustment signal AGM is fed back to OTA1 and OTA2 of the replica circuit 110. At this time, the closed loop is operated as a negative feedback loop. On the other hand, when SW1 and SW2 are in a state indicated by the broken lines of FIG. 5A, an open loop is formed, and thus a feedback process is not performed.

FIG. 5B shows a third configuration example of the switch circuit SWA. The switch circuit SWA of the third configuration example is provided between an output node of the current adding circuit 160 and a voltage storage capacitor CD. When the switch circuit SWA is turned on, a negative feedback loop is formed, and a feedback process is performed. On the other hand, when the switch circuit SWA is turned off, an open loop is formed, and a feedback process is not performed. In this case, the adjustment signal AGM is maintained in a constant voltage by the voltage storage capacitor CD.

### 1-2. Adjustment of Complex BPF Circuit

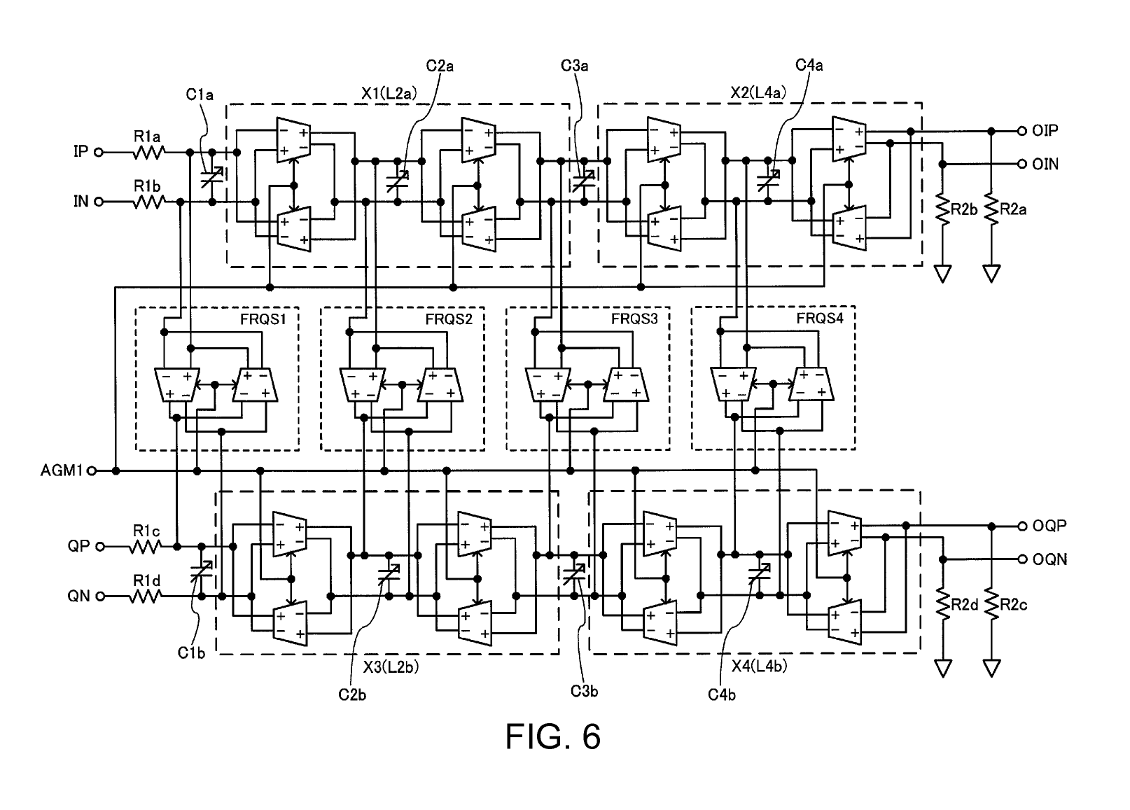

FIG. 6 is a configuration example of the complex BPF circuit 200 which is one of adjustment target circuits. The complex BPF circuit 200 shown in FIG. 6 includes resistive elements R1a to R1d and R2a to R2d, variable capacitors C1a, C1b, C3a and C3b, central frequency shift circuits FRQS1 to FRQS4, and inductor-corresponding circuits X1 to X4. In addition, the complex BPF circuit 200 of the embodiment is not limited to the configuration of FIG. 6, and may have various modifications in which some of the constituent elements thereof are omitted or replaced with other constituent elements, other constituent elements are added thereto, and the like. For example, the order of the complex BPF circuit 200 is not limited to the fourth order, may be other orders.

Each of the central frequency shift circuits FRQS1 to FRQS4 is formed by two operational transconductance amplifiers (OTAs). As described above, the low-pass filter of the first signal I system is connected to the low-pass filter of the second signal Q system via a pair of OTAs with different polarities, and thereby a frequency characteristic is shifted by the central frequency ω0. That is, it is possible to obtain a band-pass filter (fourth-order complex BPF).

The inductor-corresponding circuits X1 to X4 each of which is formed by four operational transconductance amplifiers (OTAs) and a single capacitor, and are operated as inductors L2a, L4a, L2b and L4b. If a capacitance value of the variable capacitors C2a, C4a, C2b and C4b is set to Cx, and a transconductance value of each OTA is set to gm, an inductance value L of each of the inductors L2a, L4a, L2b and L4b is given by L=Cx/gm².

Four input signals IP, IN, QP and QN have phases different from each other. A phase of IP is different from a phase of IN by 180 degrees, and a phase of QP is different from a phase of QN by 180 degrees. In other words, IP and IN, and QP and QN respectively form a pair of differential signals. In addition, a phase of IP is different from a phase of QP by 90 degrees, and a phase of IN is different from a phase of QN by 90 degrees.

The OTAs included in the central frequency shift circuits FRQS1 to FRQS4 and the inductor-corresponding circuits X1 to X4 adjust transconductance values (gm values) thereof on the basis of the adjustment signal AGM1 from the first adjustment signal generating circuit 100-1.

The complex BPF circuit 200 is operated as a band-pass filter, and, if the central frequency is set to f0, ω0 (=2×π×f0) and a gm value of each OTA are set as follows.

gm1=ω0×CC1a (9)

gm2=ω0×CC2a (10)

gm3=ω0×CC3a (11)

gm4=ω0×CC4a (12)

Here, gm1 to gm4 are transconductance values of the OTAs included in the central frequency shift circuits FRQS1 to FRQS4, and CC1a, CC2a, CC3a, and CC4a are capacitance values of the variable capacitors C1a, C2a, C3a and C4a. When a circuit is designed, the transconductance values gm1 to gm4 of the respective OTAs are set such that ω0 becomes a desired frequency. In addition, a capacitance value of each variable capacitor may be set to a desired capacitance value or a value close to the desired capacitance value in a testing process when shipment from the factory is performed.

In a practical circuit, gm fluctuates due to a manufacturing disparity, a fluctuation in a power supply voltage or temperature, or the like, and, for this reason, the central frequency ω0 and a cutoff frequency of the BPF are deviated from design values. According to the first adjustment signal generating circuit 100-1 of the embodiment, deviation of the central frequency of the replica circuit 110 (first-order complex BPF) is detected, and a transconductance value gm of the OTA can be adjusted so as to correct this deviation. Further, since ω0=gm/C as described above, correction can be performed along with a disparity of the capacitance value C by adjusting gm.

The reason why gm of the OTA is deviated from a desired value, that is, an assumed design value is that β of a tail current ISS of a MOS transistor is deviated from the assumed design value due to fluctuations in a process, a power supply voltage, and peripheral temperature. Here, β is one of parameters indicating characteristics of the MOS transistor, and is given by the following expression when a channel width is W, a channel length is L, a mobility is μ, and a capacitance per unit area of a gate oxide is Cox.

β=(W/L)·μ·Cox (13)

Therefore, if gm of all the OTAs in FIG. 6 is deviated to an extent, gm of OTA1 and OTA2 of the replica circuit 110 (FIG. 3) formed in the vicinity thereof in the same integrated circuit may also be deviated at the same ratio due to the same cause.

As above, in a case where a transconductance value gm or a capacitance value C fluctuates due to a manufacturing disparity, a fluctuation in a power supply voltage or temperature, or the like, the replica circuit 110 and the complex BPF circuit 200 fluctuate in a central frequency in the same manner. In addition, a central frequency of the replica circuit 110 may not be the same as a central frequency of the complex BPF circuit 200.

In addition, the replica circuit 110 is not limited to the first-order complex BPF, and may be a second-order or higher complex BPF. Further, the replica circuit 110 may be formed only by differential circuits in the same manner as the complex BPF circuit 200 of FIG. 6.

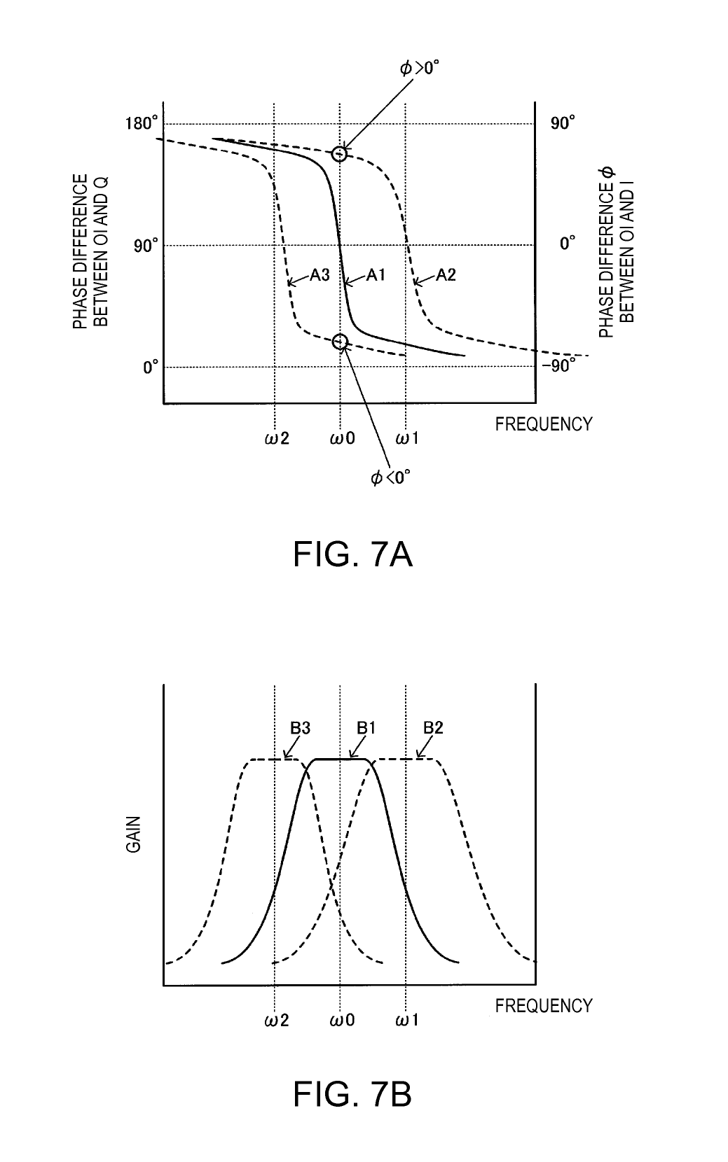

FIGS. 7A and 7B are diagrams illustrating detection of deviation of the central frequency by using the first adjustment signal generating circuit 100-1 of the embodiment. FIG. 7A shows a relationship between a phase difference of the first output signal OI relative to the first and second signals I and Q and the central frequency in the replica circuit 110. In addition, FIG. 7B shows a frequency characteristic of the complex BPF circuit 200 (for example, a fourth-order complex BPF). A design value (desired value) of a central frequency of the band-pass filter is assumed as ω0.

As shown in FIG. 7A, the replica circuit 110 (a first-order complex BPF) has a phase difference of the first output signal OI and the first signal I which varies in a range from −90 degrees to 90 degrees. Although not shown, for example, when the complex BPF circuit 200 is a fourth-order complex BPF, a phase difference varies in a range from −360 degrees to 360 degrees in a positive frequency domain.

When the central frequency conforms to the design value ω0, as shown in A1 of FIG. 7A, a phase difference φ of the first output signal OI and the first signal I is 0 degrees at the frequency ω0. In addition, a phase of the second signal Q is 90 degrees later than the first signal I in the positive frequency domain, and thus a phase difference of OI and Q is 90 degrees at the frequency ω0. A frequency characteristic of a gain of the complex BPF circuit 200 in this case is a characteristic shown in B1 of FIG. 7B.

In a case where the central frequency varies to ω1 (ω1>ω0) due to a manufacturing disparity or the like, for example, as shown in A2 of FIG. 7A, a phase difference φ of OI and I is greater than 0 degrees and a phase difference of OI and Q is greater than 90 degrees at the frequency ω0. A frequency characteristic of a gain of the complex BPF circuit 200 in this case is a characteristic shown in B2 of FIG. 7B.

In addition, in a case where the central frequency varies to ω2 (ω2<ω0) due to a manufacturing disparity or the like, as shown in A3 of FIG. 7A, a phase difference φ of OI and I is smaller than 0 degrees and a phase difference of OI and Q is smaller than 90 degrees at the frequency ω0. A frequency characteristic of a gain of the complex BPF circuit 200 in this case is a characteristic shown in B3 of FIG. 7B.

Therefore, the first and second signals I and Q with the frequency ω0 are input to the replica circuit 110, and it can be estimated based on the output signals VA1 and VA2 of the smoothing circuits LPF1 and LPF2 whether or not the central frequency of the complex BPF circuit 200 conforms to the design value ω0, and whether or not two cutoff frequencies ωH and ωL of the complex BPF circuit 200 conform to design values.

The complex BPF circuit 200 and the replica circuit 110 are formed in the same IC chip. For this reason, fluctuation causes (a fluctuation in IC manufacturing process, a power supply voltage fluctuation, a peripheral temperature fluctuation, and the like) of the central frequency and the two cutoff frequencies ωH and ωL of the complex BPF circuit 200 conform to fluctuation causes (a process fluctuation, a power supply voltage fluctuation, a peripheral temperature fluctuation, and the like) of the central frequency of the replica circuit 110.

In the circuit device 300 of the embodiment, based on this fact, instead of detecting a central frequency fluctuation and a cutoff frequency fluctuation of the complex BPF circuit 200 which is one of adjustment target circuits, a central frequency fluctuation of the replica circuit (first-order complex BPF) 110 is detected, and gm values of all the OTAs included in the replica circuit 110 and the complex BPF circuit 200 are adjusted so as to be close to design values on the basis of this detection result.

Specifically, if a difference (VA1−VA2) (FIG. 4) of the output signals of the smoothing circuits LPF1 and LPF2 is 0, it is determined that the central frequency and the two cutoff frequencies ωH and ωL conform to design values. If (VA1−VA2) is negative (that is, φ>0), it is determined that the central frequency is deviated to a higher side than ω0, and if (VA1−VA2) is positive (that is, φ<0), it is determined that the central frequency is deviated to a lower side than ω0.

In addition, although not shown, a phase difference of the second output signal OQ relative to the second signal Q is the same as a phase difference of OI relative to I of FIG. 7A. Therefore, a phase difference of OQ and I is 90 degrees at the central frequency ω0, and thus a phase difference of OQ and I may be compared. In other words, OQ and I may be used as inputs of the mixer MX.

As shown in Expression (8), if the difference (VS1−VS2) of the integration values is negative, the correction current ICR becomes negative, and thus adjustment is performed so as to reduce the transconductance (gm). When gm is reduced, the central frequency (=gm/C) is also reduced and becomes close to the design value ω0. On the other hand, if the difference (VS1−VS2) of the integration values is positive, the correction current ICR becomes positive, and thus adjustment is performed so as to increase the transconductance. When gm increases, the central frequency also increases and becomes close to the design value ω0. In addition, in a case where the central frequency conforms to the design value ω0, the difference (VA1−VA2) of the output signals of the smoothing circuits becomes 0, and, thereafter, the difference (VS1−VS2) of the integration values is maintained in a constant voltage, and thus gm is also maintained in a constant value.

In addition, a method of adjusting gm of the OTA by using the adjustment signal AGM1 will be described later.

As described above, the adjustment of the transconductance is performed on not only the OTAs included in the replica circuit 110 but also the OTAs included in the complex BPF circuit 200 in the same manner, and thus the central frequency and the two cutoff frequencies ωH and ωL of the complex BPF circuit 200 are also corrected to design values. As described above, since there is a relationship of ω0=gm/C, gm is adjusted, and thereby the central frequency can be corrected including a fluctuation in the capacitance value C of the capacitor. For example, in a case where the capacitance value C varies to k times the magnitude of a design value, a gm value is also adjusted to k times the magnitude of the design value, and thereby the central frequency can be corrected to the design value.

In addition, if products of inductance values of the inductor-corresponding circuits X1 to X4 (FIG. 6) and the capacitance values of the adjacent variable capacitors C1a, C3a, C1b and C3b are maintained in predetermined design values, characteristics of the complex BPF circuit 200 is maintained. For example, when an inductance value of X1 (L2a) is LL2a, and capacitance values of the adjacent variable capacitors C1a and C3a are respectively CC1a and CC3a, if products LL2a×CC1a and LL2a×CC3a of the inductance values and the capacitance values are maintained in predetermined design values, characteristics of the complex BPF circuit 200 are maintained. Here, as described above, since there is a relationship of LL2a=CC2a/gm², the following expressions are given.

LL2a×CC1a=CC2a×CC1a/gm² (14)

LL2a×CC3a=CC2a×CC3a/gm² (15)

As can be from above-described expressions, even in a case where the capacitance value varies to k times the magnitude of a design value, the gm value is adjusted to k times the magnitude of the design value, and thereby a product of the inductance value and the capacitance value can be maintained in a constant value.

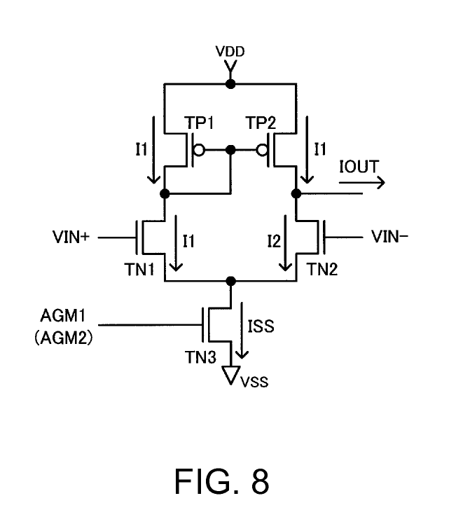

FIG. 8 shows a first configuration example of the operational transconductance amplifier (OTA) included in the replica circuit 110 and the complex BPF circuit 200. In addition, the OTA of the embodiment is not limited to the configuration of FIG. 8, and may have various modifications in which some of the constituent elements thereof are omitted or replaced with other constituent elements, other constituent elements are added thereto, and the like.

The first configuration example of the OTA shown in FIG. 8 includes N type transistors TN1, TN2 and TN3, and P type transistors TP1 and TP2. A gate of TN1 is connected to a non-inverting input terminal VIN+, and a gate of TN2 is connected to an inverting input terminal VIN−. TP1 and TP2 form a current mirror circuit. A drain of TN1, drain and gate of TP1, and a gate of TP2 are connected in common to each other. In addition, a drain of TN2 and a drain of TP2 are connected in common to each other, and are further connected to a current output terminal IOUT. TN3 is operated as a current source of a tail current ISS, and a gate bias voltage is adjusted by the adjustment signal AGM1 input to the gate thereof, so as to adjust a current value of the tail current ISS.

Since TN3 and TN4 of the current adding circuit 160 (FIG. 4) form a current mirror circuit, a current value of the drain current (the tail current ISS) of TN3 is proportional to a current value of the drain current (ICR+IREF) of TN4. This proportional constant is defined by the sizes of TN3 and TN4. For example, when the channel lengths of TN3 and TN4 are the same, the proportional constant is a ratio of the channel widths thereof. In this way, a current value of the tail current ISS of the OTA is set to be proportional to (ICR+IREF).

The transconductance gm of the OTA is expressed by the following expression using the tail current ISS.

gm=\sqrt{β·ISS} (16)

In the expression, β is a characteristic parameter of TN1 and TN2 given by Expression (13). A derivation of this Expression (16) is disclosed, for example, in “Introduction to CMOS Analog Circuits” written by Kenji TANIGUCHI, fourth edition (Aug. 1, 2006, CQ Publishing Co., Ltd.) P 101 to P 103, which is a published document.

As can be seen from Expression (16), it is possible to adjust gm of the OTA by adjusting the tail current ISS. As described above, since TN4 included in the current adding circuit 160 and TN3 which is a tail current source form a current mirror circuit, it is possible to obtain a tail current ISS which is proportional to the drain current (Ids=ICR+IREF) of TN4.

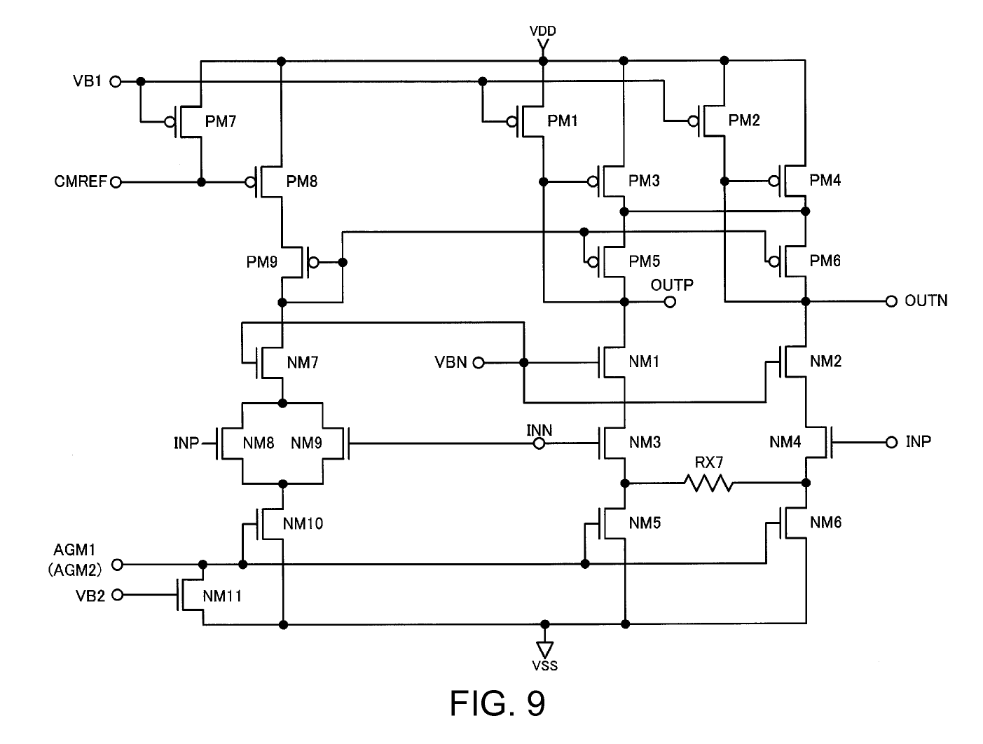

FIG. 9 shows a second configuration example of the operational transconductance amplifier (OTA). In addition, the OTA of the embodiment is not limited to the configuration of FIG. 9, and may have various modifications in which some of the constituent elements thereof are omitted or replaced with other constituent elements, other constituent elements are added thereto, and the like.

In the second configuration example of the OTA shown in FIG. 9, N type transistors NM3 and NM4 form a pair of differential inputs of the OTA, and gates thereof are respectively connected to input terminals INN and INP. P type transistors PM5 and PM6 form a load current source, and drains thereof are respectively connected to output terminals OUTP and OUTN. A bias voltage VBN is input to gates of N type transistors NM1 and NM2 which are cascode-connected to a pair of differential inputs NM3 and NM4. NM1 and NM2 perform a function of increasing an output impedance of the OTA so as to reduce influence of a fluctuation in a load. N type transistors NM5 and NM6 form a current source of a tail current, and the tail current of the OTA is adjusted by the adjustment signal AGM1 input to each of gates thereof. The tail current is adjusted, and thereby gm of the OTA is adjusted.

P type transistors PM3, PM4 and PM8 are common feedback transistors, and perform a function of stabilizing a DC potential of an operation point of the OTA. In addition, a P type transistor PM9 and N type transistors NM7, NM8 and NM9 form a bias voltage generating circuit, and generate a gate bias voltage of the load current source PM5 and PM6.

In addition, OTA1 and OTA2 included in the replica circuit 110 of the second adjustment signal generating circuit 100-2 also have the same configuration as the OTA of the first or second configuration example described above.

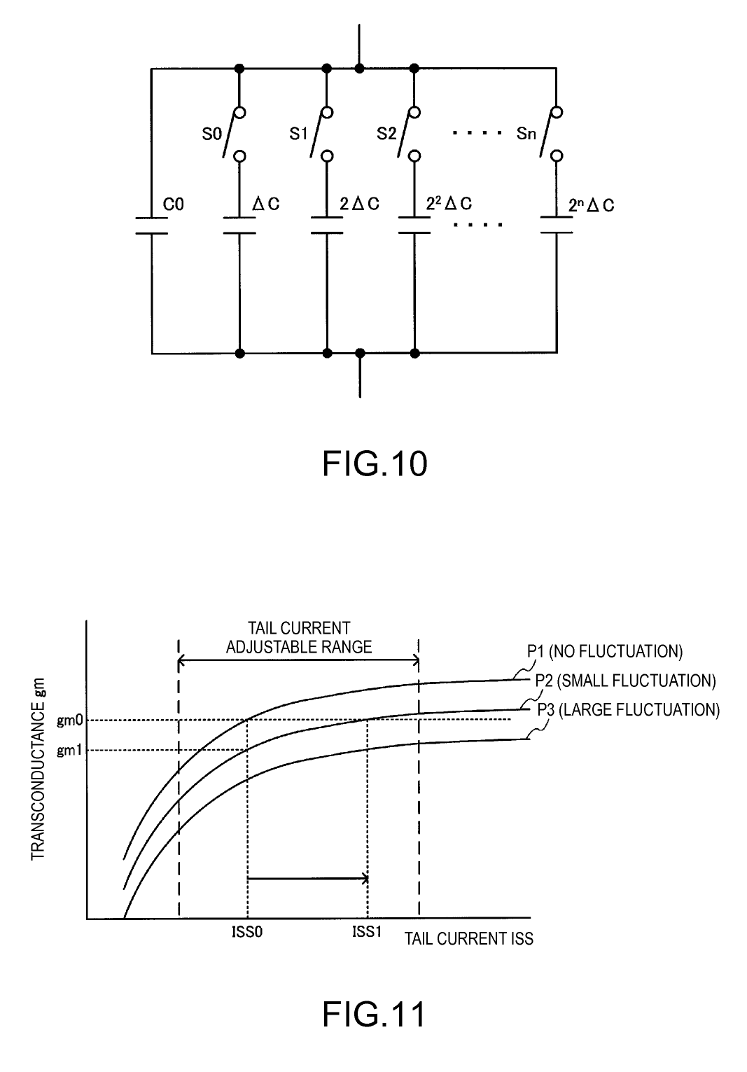

FIG. 10 shows a configuration example of the variable capacitors CA1 and CA2 (FIG. 3) included in the replica circuit 110 and the variable capacitors C1a, C1b, C3a and C3b (FIG. 6) included in the complex BPF circuit 200. The variable capacitors shown in FIG. 10 include (n (where n is 0 or a natural number)+2) capacitors and (n+1) switching elements S0 to Sn, and capacitance values of the capacitors are respectively C0, ΔC, 2ΔC, 2²ΔC, . . . , and 2ⁿΔC.

The switching elements S0 to Sn are turned on and off, for example, based on capacitance value setting information stored in a nonvolatile memory such EEPROM provided in the circuit device 300. Specifically, the capacitance value setting information is formed by (n+1) bits, and the switching elements S0 to Sn are turned on and off based on 1 or 0 of each bit. For example, if n=2, when the capacitance value setting information is “000”, S0, S1, and S2 are all turned off, and an overall capacitance value is C0. In addition, when the capacitance value setting information is “001”, S0 is turned on, S1 and S2 are turned off, and thus an overall capacitance value is C0+ΔC. Further, when the capacitance value setting information is “010”, S0 is turned off, S1 is turned on, S2 are turned off, and thus an overall capacitance value is C0+2ΔC. In this way, an overall capacitance value can be set in increments of ΔC with C0 as the minimum value.

In a testing process or the like before shipment from the factory is performed, for example, the capacitance value setting information is stored in a nonvolatile memory such as EEPROM provided in the circuit device 300, and thereby a capacitance value of the variable capacitor can be set to a desired capacitance value or a value close to the desired capacitance value.

In addition, the switching elements S0 to Sn of FIG. 10 may be replaced with a fuse, an anti-fuse, or the like. In this case, in a testing process when shipment from the factory is performed, the fuse is disconnected or the anti-fuse is conducted, and thereby a capacitance value of the variable capacitor can be set to a desired capacitance value or a value close to the desired capacitance value.

As above, according to the circuit device 300 of the embodiment, in a testing process when shipment from the factory is performed, a capacitance value of the variable capacitor is adjusted, and a central frequency can be adjusted by the adjustment signal AGM1 of the first adjustment signal generating circuit 100-1 when used for practical communication. In this way, it is possible to reduce an adjustment amount (adjustment range) of gm. FIG. 11 illustrates relationship between the transconductance gm and the tail current ISS in OTA, where P1, P2 or P3 follows the expression (16). This figure shows the larger the adjustment range of gm (gm0-gm1) is, the more dynamically the tail current needs to change (ISS1-ISS0).

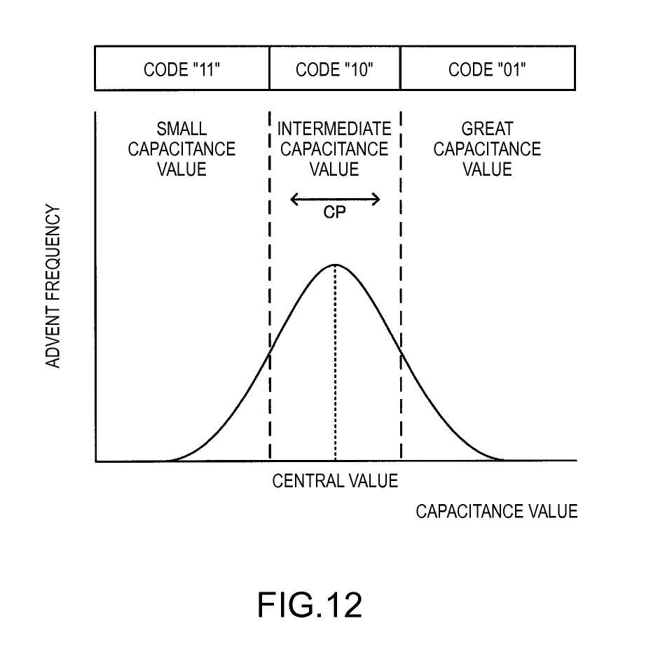

FIG. 12 is a diagram that shows how capacitance value is distributed in actual IC chips between different chips or between different wafers due to fluctuation of IC manufacturing process or depending on the location of the chip. It is also illustrating how adjustment of a capacitance value is done using a variable capacitor at testing process in IC manufacturing facility of the integrated circuit. In FIG. 12, the transverse axis expresses a capacitance value, and the longitudinal axis expresses frequency of the capacitance value occurs. For example, it is assumed that capacitance values are distributed as shown in FIG. 12. In this case, the capacitance values are classified into three groups depending on the magnitudes thereof, and are correlated with codes (capacitance value setting information, for example, “11”, “10”, and “01”) for adjusting a capacitance. In addition, a capacitance value of the variable capacitor can be set based on these codes. Specifically, in a case where the variable capacitor includes S0, S1, C0, ΔC, and 2ΔC shown in FIG. 10, both of S0 and S1 are turned on according to the code “11”, and thus a capacitance value is set to C0+3ΔC. In addition, according to the code “10”, S0 is turned off, S1 is turned on, and a capacitance value is set to C0+2ΔC. Further, according to the code “01”, S0 is turned on, S1 is turned off, and a capacitance value is set to C0+ΔC. In this way, the distribution of the capacitance values can be made to be in a range indicated by CP of FIG. 12, and thus it is possible to narrow a range in which gm is to be adjusted.

### 1-3. Adjustment of Mixer, PLL Circuit, Low-Noise Amplifier, and the Like

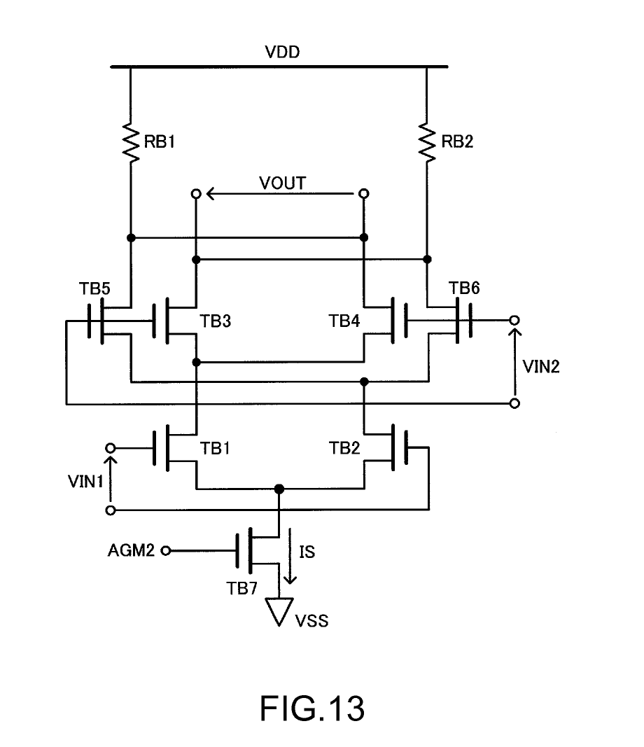

FIG. 13 shows a configuration example of the mixer 330. In addition, the mixer 330 of the embodiment is not limited to the configuration of FIG. 13, and may have various modifications in which some of the constituent elements thereof are omitted or replaced with other constituent elements, other constituent elements are added thereto, and the like.

The configuration example of the mixer 330 shown in FIG. 13 includes N type transistors TB1 to TB7, and resistive elements RB1 and RB2. An input signal VIN1 is input to each of gates of TB1 and TB2, and an input signal VIN2 is input to each of gates of TB3 to TB6. An output signal VOUT is output from a common connection node of TB3 and TB6 and a common connection node of TB4 and TB5. TB7 is a transistor forming a tail current source, a tail current is adjusted by the adjustment signal AGM2 which is input to a gate thereof, and gm of the mixer 330 is adjusted by adjusting the tail current.

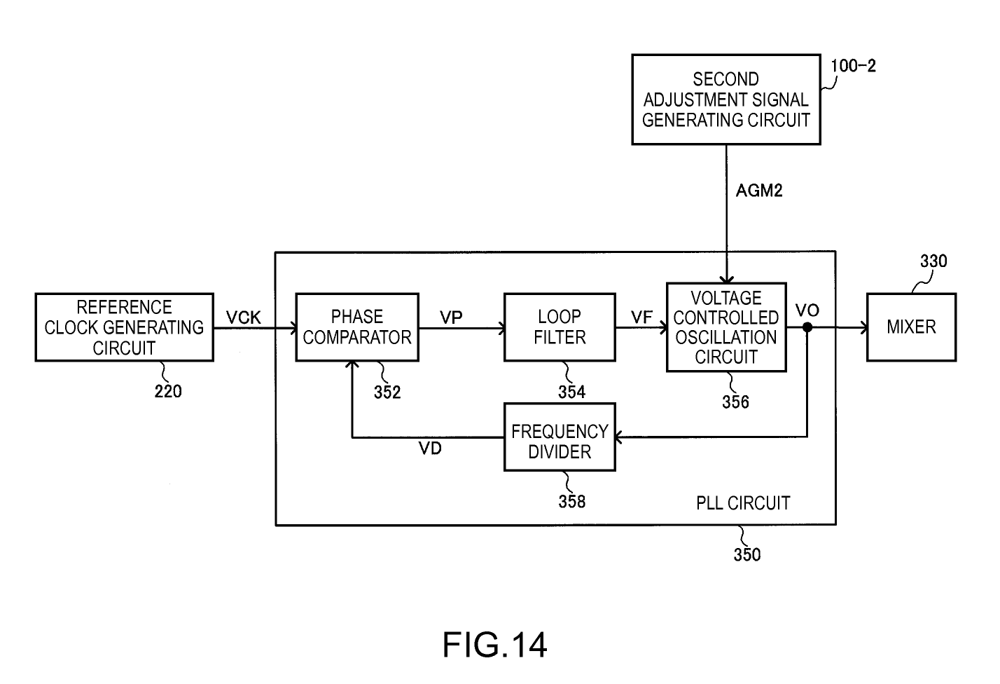

FIG. 14 shows a configuration example of the reception PLL circuit 350 of the embodiment. The reception PLL circuit 350 includes a phase comparator 352, a loop filter 354, a voltage controlled oscillation circuit (LC-VCO) 356, and a frequency divider 358, and generates a signal with a local frequency which is output to the mixer 330. In addition, the reception PLL circuit 350 of the embodiment is not limited to the configuration of FIG. 14, and may have various modifications in which some of the constituent elements thereof are omitted or replaced with other constituent elements, other constituent elements are added thereto, and the like.

The reference clock generating circuit 220 generates a reference clock VCK which is output to the phase comparator 352. The phase comparator 352 compares the reference clock signal VCK with a frequency-divided signal VD so as to output an output signal VP. The loop filter 354 removes a high frequency component included in the output signal VP of the phase comparator 352 and outputs only a low frequency component to the voltage controlled oscillation circuit 356 as a frequency control signal VF. The voltage controlled oscillation circuit 356 oscillates at a frequency corresponding to the frequency control signal VF so as to output an oscillation output signal VO. The frequency divider 358 frequency-divides the oscillation output signal VO so as to output a frequency-divided signal VD.

By repeatedly performing the above-described operations, finally, an oscillation frequency is set to a frequency which is N times (where N is a division ratio of the frequency divider 358) the magnitude of a frequency of the reference clock VCK. This finally set frequency is a desired local frequency.

In addition, the transmission PLL circuit 230 of the embodiment may have the same configuration as the reception PLL circuit 350 shown in FIG. 14.

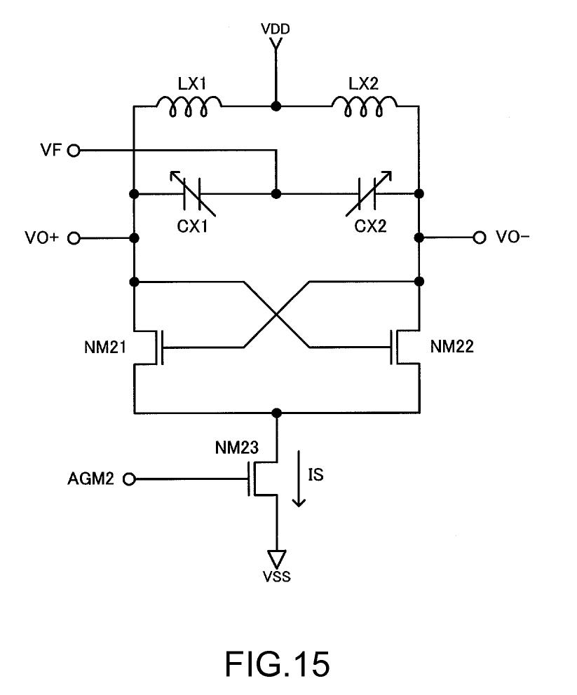

FIG. 15 shows a configuration example of the voltage controlled oscillation circuit 356 of the embodiment. The voltage controlled oscillation circuit 356 of the configuration example is an LC tank type voltage controlled oscillation circuit (LC-VCO), and includes N type transistors NM21, NM22 and NM23, inductors (coils) LX1 and LX2, and frequency control varactors CX1 and CX2. In addition, the voltage controlled oscillation circuit 356 of the embodiment is not limited to the configuration of FIG. 15, and may have various modifications in which some of the constituent elements thereof are omitted or replaced with other constituent elements, other constituent elements are added thereto, and the like.

The inductors LX1 and LX2 and the frequency control varactors CX1 and CX2 form an LC resonance circuit, and control an oscillation frequency by varying a voltage VF applied to CX1 and CX2 so as to vary capacitance values of CX1 and CX2. The N type transistor NM23 is a transistor forming a tail current source, a tail current is adjusted by the adjustment signal AGM2 which is input to a gate thereof, and gm of the voltage controlled oscillation circuit 356 is adjusted by adjusting the tail current.

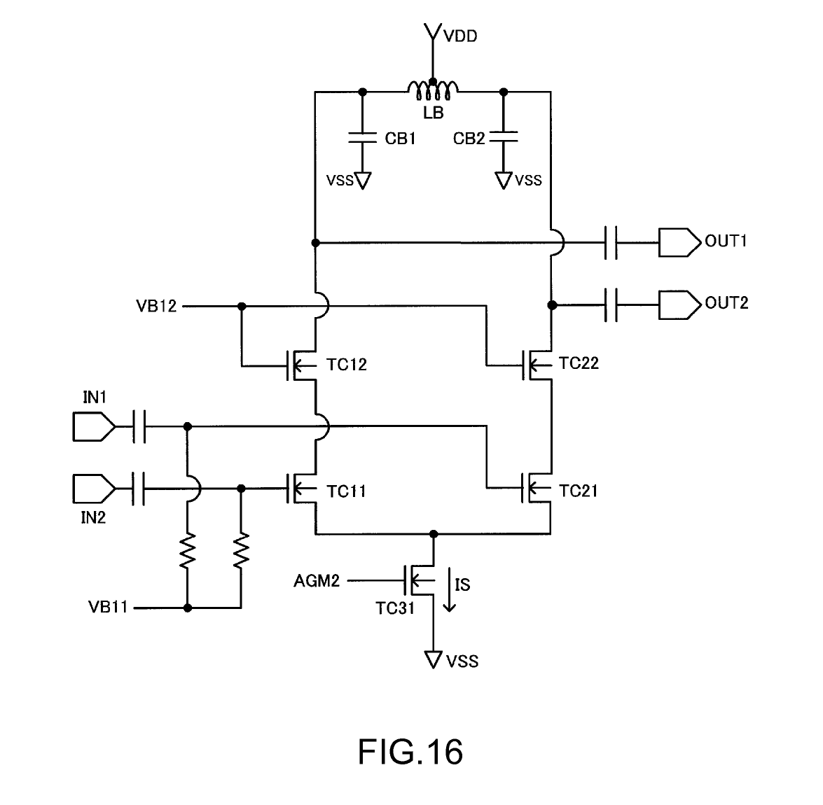

FIG. 16 shows a configuration example of the low-noise amplifier (LNA) 320 of the embodiment. The low-noise amplifier (LNA) 320 of the configuration example includes N type transistors TC11, TC12, TC21, TC22 and TC31, an inductor (coil) LB, and capacitors CB1 and CB2. In addition, the low-noise amplifier (LNA) 320 of the embodiment is not limited to the configuration of FIG. 16, and may have various modifications in which some of the constituent elements thereof are omitted or replaced with other constituent elements, other constituent elements are added thereto, and the like.

The N type transistors TC11, TC12, TC21 and TC22 form a cascode-connected amplification transistor. In addition, the inductor (coil) LB, and the capacitors CB1 and CB2 form an LC load circuit. The N type transistor TC31 is a transistor forming a tail current source, a tail current is adjusted by the adjustment signal AGM2 which is input to a gate thereof, and gm of the low-noise amplifier (LNA) 320 is adjusted by adjusting the tail current.

Although a configuration example of the power amplifier (PA) 240 of the embodiment is not shown, for example, a configuration of a differential amplifier similar to the low-noise amplifier (LNA) 320 of FIG. 16 may be employed. In addition, the adjustment signal AGM2 is input to a gate of a transistor forming a tail current source, and thereby gm can be adjusted.

In order to adjust gm of the circuit to a design value (a target value, a desired value) with high accuracy by using the second adjustment signal generating circuit 100-2, a capacitance value C of the variable capacitors CA1 and CA2 in the replica circuit 110 of the second adjustment signal generating circuit 100-2 is required to be set to a desired value (design value). By using the variable capacitor shown in FIG. 10, the capacitance value C can be set to the desired value (design value) in a testing process or the like when shipment from the factory is performed.

Specifically, for example, in a case where a predetermined test mode is set in order to monitor a capacitance value of the variable capacitors CA1 and CA2, a terminal (inspection terminal) behaving as a terminal for inspection is provided, and an external resistive element is connected to the inspection terminal so as to measure an RC time constant. A resistance value R of the external resistive element is accurately known, and thus an RC time constant corresponding to a desired capacitance value C can be calculated accurately. The RC time constant is measured while varying the capacitance value C of the variable capacitors CA1 and CA2 such that the RC time constant becomes a desired value, and thereby the capacitance value C can be set to a desired capacitance value.

In this way, a capacitance value of the variable capacitors CA1 and CA2 of the second adjustment signal generating circuit 100-2 can be set to a desired value (design value). In addition, since gm of the low-noise amplifier (LNA) 320, the mixer 330, the PLL circuits 230 and 350, or the power amplifier (PA) 240 can be adjusted by the adjustment signal AGM2 output by the second adjustment signal generating circuit 100-2, it is possible to correct fluctuations in circuit characteristics due to a manufacturing disparity, a fluctuation in a power supply voltage or temperature, or the like.

In addition, a generation process of the adjustment signal AGM2 by the second adjustment signal generating circuit 100-2 is performed in the same manner as in the above-described first adjustment signal generating circuit 100-1. However, a capacitance value of the variable capacitors CA1 and CA2 may be different from that of CA1 and CA2 of the first adjustment signal generating circuit 100-1, and thus a voltage value of the adjustment signal AGM2 may be different from a voltage value of the adjustment signal AGM1.

As described above, according to the circuit device 300 of the embodiment, a phase error of the replica circuit 110 is detected, and a transconductance is adjusted based on the detection result. Thereby, it is possible to correct deviation from a design value (desired value) of a central frequency of the complex BPF circuit 200 and circuit characteristics of the low-noise amplifier (LNA) 320, the mixer 330, the PLL circuits 230 and 350, or the power amplifier (PA) 240. As a result, in a case where the circuit device 300 of the embodiment is used for a wireless apparatus or the like, it is possible to correct deviation from a design value (desired value) of a central frequency and circuit characteristics due to a manufacturing disparity, a fluctuation in a power supply voltage or temperature, or the like. In addition, a phase error of the replica circuit 110 is detected so as to generate adjustment signals AGM before wireless communication starts, and at least some circuits of the adjustment signal generating circuits 100 can be set in a disenable mode or a low power consumption mode after the adjustment signals AGM are generated. Therefore, it is possible to reduce power consumption during communication. As a result, it is possible to realize more stable and reliable wireless communication without increasing power consumption.

Further, since the circuit device 300 of the embodiment employs a method in which a voltage of the adjustment signal AGM is maintained by the capacitor, it is possible to perform adjustment on an adjustment target circuit with a simple configuration and low power consumption, for example, as compared with a method in which the adjustment signal AGM is converted into a digital value which is stored in a register or the like.

### 2. Electronic Apparatus

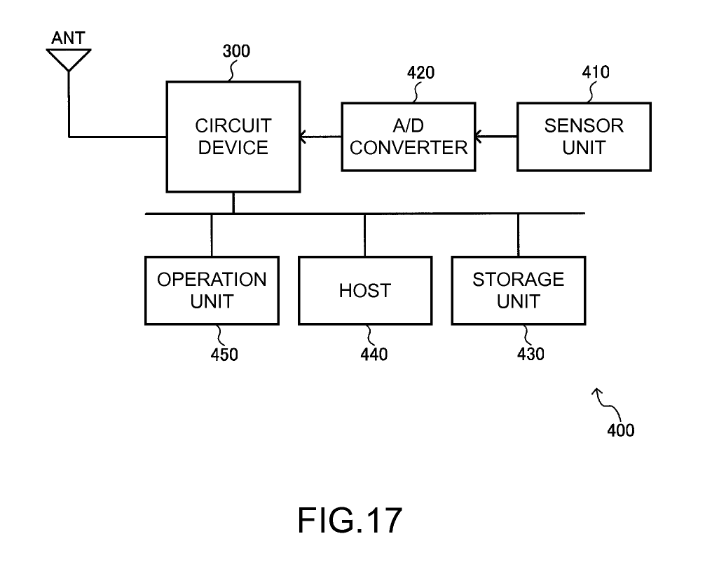

FIG. 17 shows a configuration example of an electronic apparatus 400 including the circuit device 300 of the embodiment. The electronic apparatus 400 of the embodiment includes the circuit device 300, a sensor unit 410, an A/D converter 420, a storage unit 430, a host 440, and an operation unit 450.

The electronic apparatus 400 is, for example, a thermometer, a hygrometer, a pulsometer, a pedometer, or the like, and can transmit detected data in a wireless manner. The sensor unit 410 includes a temperature sensor, a humidity sensor, a gyro-sensor, an acceleration sensor, a photosensor, a pressure sensor, and the like, and uses a sensor suitable for usage of the electronic apparatus 400. The sensor unit 410 amplifies an output signal (sensor signal) of a sensor, and removes noise by using a filter. The A/D converter 420 converts the amplified signal into a digital signal which is output to the circuit device 300. The host 440 includes, for example, a microcomputer or the like, processes a digital signal, or controls the electronic apparatus 400 on the basis of setting information stored in the storage unit 430 or a signal from the operation unit 450. The storage unit 430 includes, for example, a flash memory, and stores setting information or detected data. The operation unit 450 includes, for example, a keypad or the like, and is used for a user to operate the electronic apparatus 400.

In addition, although the embodiment has been described in detail as above, it can be easily understood by a person skilled in the art that modifications are possible without substantially departing from the new matters and effects of the invention. Therefore, these modification Examples are all intended to be included in the scope of the invention. For example, in the specification or the drawings, a terminology described along with another terminology which has a broader meaning or the same meaning may be replaced with another terminology in any location of the specification or the drawings. In addition, configurations and operations of the circuit device and the electronic apparatus are not limited to those described in the embodiment, and may have various modifications.

What is claimed is:

1. A circuit device comprising:
a communication circuit that includes at least an adjustment target circuit; and
an adjustment signal generating circuit that outputs an adjustment signal which adjusts a transconductance of the adjustment target circuit,
wherein the adjustment signal generating circuit performs a generation process of the adjustment signal, accumulates charge corresponding to the generated adjustment signal in a capacitor, and outputs the adjustment signal based on the charge accumulated in the capacitor to the adjustment target circuit.

2. The circuit device according to claim 1, wherein the adjustment signal generating circuit performs the generation process of the adjustment signal, accumulates charge corresponding to the generated adjustment signal in the capacitor, and outputs the adjustment signal based on the charge accumulated in the capacitor to the adjustment target circuit, during a signal non-communication period which is a period when the communication circuit does not perform transmission or reception of a communication signal.

3. The circuit device according to claim 1, further comprising:
a control unit that controls the adjustment signal generating circuit,
wherein the control unit sets at least a part of the adjustment signal generating circuit in a disenable state or a low power consumption mode after the adjustment signal is generated.

4. The circuit device according to claim 3, wherein the adjustment signal generating circuit includes a replica circuit of the adjustment target circuit,
wherein the adjustment signal generating circuit performs a feedback process by using a negative feedback loop including the replica circuit when the adjustment signal is generated, and
wherein the control unit switches the negative feedback loop to an open loop after the adjustment signal is generated.

5. The circuit device according to claim 4, wherein the replica circuit is a complex band-pass filter circuit, and
wherein the adjustment signal is a signal which adjusts a central frequency of the complex band-pass filter circuit.

6. The circuit device according to claim 5, wherein the replica circuit includes a variable capacitor of which a capacitance value is set to be variable.

7. The circuit device according to claim 4, wherein the adjustment signal generating circuit accumulates charge corresponding to an error from a desired value of the transconductance of the adjustment target circuit in the capacitor, and generates the adjustment signal.

8. The circuit device according to claim 4, wherein the adjustment signal generating circuit further includes:
a reference signal generating circuit that outputs a first signal and a second signal of which a phase is different from a phase of the first signal by 90 degrees to the replica circuit;
a mixer to which the second signal and a first output signal from the replica circuit, or the first signal and a second output signal from the replica circuit are input; and
a smoothing circuit that smooths an output signal from the mixer,
wherein the mixer detects a phase error of two input signals, and
wherein the smoothing circuit outputs a voltage corresponding to the detected phase error.

9. The circuit device according to claim 8, wherein the adjustment signal generating circuit further includes:
an integration circuit that accumulates charge corresponding to the detected phase error in the capacitor, and
wherein the adjustment signal generating circuit generates and outputs the adjustment signal based on the charge accumulated in the capacitor.

10. The circuit device according to claim 9, wherein the adjustment signal generating circuit further includes a switch circuit, and
wherein the control unit controls the switch circuit so as to perform control of a feedback process by using the negative feedback loop when the adjustment signal is generated, and so as to switch the negative feedback loop to the open loop after the adjustment signal is generated.

11. The circuit device according to claim 1, wherein the adjustment signal generating circuit functions as a first adjustment signal generating circuit, and
wherein the first adjustment signal generating circuit outputs a first adjustment signal to a complex band-pass filter circuit that is one of components of the communication circuit as the adjustment signal.

12. The circuit device according to claim 11, wherein the complex band-pass filter circuit included in the communication circuit includes a variable capacitor of which a capacitance value is set to be variable, and
wherein the first adjustment signal generating circuit adjusts a central frequency of the complex band-pass filter circuit by using the first adjustment signal after a capacitance value of the variable capacitor is adjusted.

13. The circuit device according to claim 1, wherein the adjustment signal generating circuit functions as a second adjustment signal generating circuit, and
wherein the second adjustment signal generating circuit outputs a second adjustment signal to at least one of a low-noise amplifier, a mixer, a PLL circuit, and a power amplifier included in the communication circuit, as the adjustment signal.

14. An electronic apparatus comprising the circuit device according to claim 1.

15. An electronic apparatus comprising the circuit device according to claim 2.

16. An electronic apparatus comprising the circuit device according to claim 3.

17. An electronic apparatus comprising the circuit device according to claim 4.

18. An electronic apparatus comprising the circuit device according to claim 5.

19. An electronic apparatus comprising the circuit device according to claim 6.

20. An electronic apparatus comprising the circuit device according to claim 7.
